(19) United States
(12) Patent Application Publication
(10) Pub. No.: US 2014/0327094 A1
(43) Pub. Date: Nov. 6, 2014

(54) SEMICONDUCTOR STRUCTURE FOR ELECTROMAGNETIC INDUCTION SENSING AND A METHOD OF MANUFACTURING THE SAME

(71) Applicant: Feeling Technology Corp., Hsinchu (TW)

(72) Inventors: TENG-TSAI LIN, HSINCHU (TW); WEN-JUNG SU, HSINCHU (TW); HSUAN-CHUAN CHEN, HSINCHU (TW)

(73) Assignee: FEELING TECHNOLOGY CORP., Hsinchu (TW)

(21) Appl. No.: 13/966,569

(22) Filed: Aug. 14, 2013

(30) Foreign Application Priority Data
May 3, 2013 (TW) 102115893
Jun. 21, 2013 (TW) 102122143

(51) Int. Cl. H01L 43/06; H01L 43/14; G01R 33/07

(52) U.S. Cl. CPC H01L 43/065; G01R 33/07; H01L 43/14
USPC 257/421; 438/3

(57) ABSTRACT

A semiconductor structure for electromagnetic induction sensing and a method for manufacturing the same are provided: forming the Hall sensor in a first semiconductor fabrication; forming the passivation layer above the Hall sensor to cover the Hall sensor according to the first semiconductor fabrication; and forming the current-carrying layer above the passivation layer in a second semiconductor fabrication to form the semiconductor structure for electromagnetic induction sensing. The current-carrying layer carries the current to be sensed; and the Hall sensor senses the magnetic field generated. The Hall sensor generates a voltage or a current signal proportional to the strength of the current to be sensed.

This application claims the benefits of the Taiwan Patent Application Serial NO. 102115893 filed on May 3, 2013 and Serial NO. 102122143 filed on Jun. 21, 2013, the subject matters of which are incorporated herein by reference.

### BACKGROUND OF THE INVENTION

1. Field of the Invention

The present invention relates to a semiconductor structure for electromagnetic induction sensing and a method of manufacturing the same and more particularly, relates to a semiconductor structure for electromagnetic induction sensing including a current-carrying layer formed with a semiconductor fabrication and close to a Hall sensor in a wafer fabrication, and a method of manufacturing the same.

2. Description

At present, a Hall sensor is frequently utilized for contactless current sensing. The Hall sensor is disposed near a current route carrying a current to be sensed; a change of magnetic field is generated and a sensed voltage or current is generated when a magnetic flux goes through the Hall sensor. Generally speaking, the higher density of the magnetic flux is, the greater strength of the sensed voltage or current will be. Accordingly, the strength of the sensed voltage or current can be determined so the strength of the current to be sensed can be predicted. As a result, a contactless current sensing can be accomplished.

The magnetic flux generated by the current becomes weaker when it is farther from the current. Therefore, it is better if a current route is disposed close to the Hall sensor for the Hall sensor to fetch greater magnetic flux. At present, a current-carrying lead frame is utilized as the current route. Although a lead frame can tolerate greater currents such as a current over 200 amperes and although a lead frame can be stored within the same module as a chip including the Hall sensor, the distance between the lead frame and the Hall sensor is still too great.

Besides, when the lead frame is fabricated during an assembly process, the distance between the lead frame and the chip is deformed and unstable for being squeezed by molding compound. Also, during a wafer fabrication, it is necessary to save rooms for thermal expansion, welding and fault tolerance for the next process; thus, spaces of a wafer are not utilized more effectively.

Therefore, it is important to shorten the distance between the current route and the Hall sensor, to control an interval distance between the current route and the Hall sensor, and to eliminate the wasted space when fabricating a semiconductor.

### SUMMARY OF THE INVENTION

In prior art, when the lead frame is fabricated during an assembly process, the distance between the lead frame and the chip is deformed and unstable for being squeezed by molding compound. Also, during a wafer fabrication, it is necessary to save rooms for thermal expansion, welding and fault tolerance for the next process.

Therefore, a semiconductor structure for electromagnetic induction sensing is provided according to embodiments of the present invention. The semiconductor structure includes at least a Hall sensor, a passivation layer and a current-carrying layer. The Hall sensor senses a magnetic field generated by a current to be sensed; the passivation layer is disposed on the Hall sensor to cover the Hall sensor; and the current-carrying layer carries the current to be sensed, is disposed on the passivation layer and is separated from the Hall sensor within an effective distance so that the Hall sensor senses the magnetic field.

Besides, a method of manufacturing the semiconductor structure during a wafer fabrication is provided according to embodiments of the present invention. The method includes following steps: (a) forming the Hall sensor in a first semiconductor fabrication; (b) forming the passivation layer above the Hall sensor to cover the Hall sensor according to the first semiconductor fabrication; and (c) forming the current-carrying layer above the passivation layer in a second semiconductor fabrication to form the semiconductor structure for electromagnetic induction sensing, wherein the current-carrying layer is separated from the Hall sensor within the effective distance.

Further, according to embodiments of the present invention, the first semiconductor fabrication includes diffusing, depositing and ion implanting, and the second semiconductor fabrication includes sputter coating, depositing and etching. To be more specific, in other embodiments of the present invention, the second semiconductor fabrication includes fabricating a Redistribution Layer (RDL). The passivation layer includes an effective thickness and the current-carrying layer includes an effective width; the effective thickness is less than 100 um, the effective distance is less than 500 um, and the effective width is larger than 1 um. There is an angle between the Hall sensor and the passivation layer and the angle is larger than 0 degree and smaller than or equal to 90 degrees. The passivation layer is selected from the group of an oxide, a nitride and a polyimide. The current-carrying layer is selected from the group of a high conductivity metal and an alloy.

The current-carrying layer is fabricated during a wafer fabrication and the current-carrying layer is closed to the Hall sensor; that is, the current-carrying layer is not fabricated after a wafer dicing stage; therefore, the current-carrying layer is not deformed and unstable for being squeezed by molding compound. Also, there is no need to save rooms for thermal expansion, welding and fault tolerance; spaces of a wafer are utilized more effectively.

### BRIEF DESCRIPTION OF THE DRAWINGS

Other features and advantages of this invention will become more apparent in the following detailed description of the preferred embodiments of this invention, with reference to the accompanying drawings

FIGS. 1A and 1B are schematic views showing an electromagnetic principle utilized in embodiments of the present invention.

FIG. 2A is a schematic view of a semiconductor structure for electromagnetic induction sensing according to a first embodiment of the present invention.

FIG. 2B is a schematic and top view of the semiconductor structure for electromagnetic induction sensing according to the first embodiment of the present invention.

FIG. 3 is a schematic view of a semiconductor structure for electromagnetic induction sensing according to a second embodiment of the present invention.

FIG. 4 is a schematic and top view of a semiconductor structure for electromagnetic induction sensing according to a third embodiment of the present invention.

FIG. 5 is a schematic and top view of a semiconductor structure for electromagnetic induction sensing according to a fourth embodiment of the present invention.

FIG. 6 is a schematic and top view of a semiconductor structure for electromagnetic induction sensing according to a fifth embodiment of the present invention.

FIG. 7 is a flow chart showing a method of manufacturing a semiconductor structure for electromagnetic induction sensing according to embodiments of the present invention.

### DETAILED DESCRIPTION OF THE PREFERRED EMBODIMENT

The present invention relates to a semiconductor structure for electromagnetic induction sensing. In the following description, numerous details are set forth in order to provide a thorough understanding of the present invention. It will be appreciated by one skilled in the art that variations of these specific details are possible while still achieving the results of the present invention. In other instance, well-known components are not described in detail in order not to unnecessarily obscure the present invention.

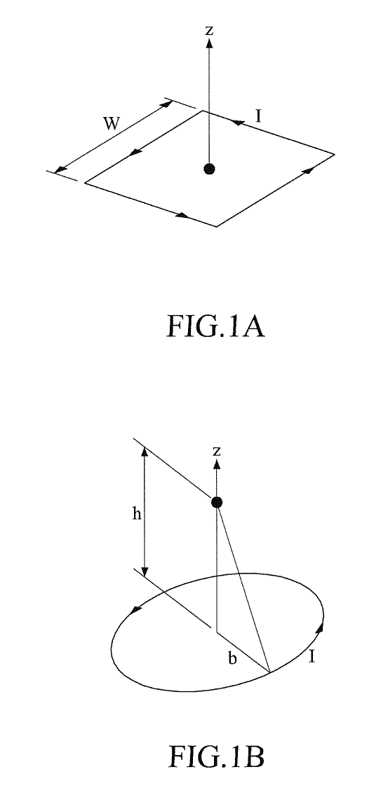

Refer to FIG. 1A and 1B, the schematic views showing an electromagnetic principle utilized in embodiments of the present invention. FIG. 1A illustrates a magnetic flux density when a current I is formed as a square loop with its width of W, wherein the magnetic flux density at the center of the square is \vec{B}=α_{z}2\sqrt{2}μ₀I/πw.

FIG. 1B illustrates a magnetic flux density when the current I is formed as a circle with its radius of b, wherein the magnetic flux density at the height of h on the z axis is \vec{B}=\hat{α}_{z}μ₀Ib²/2(h²+b²)^{3/2}. Accordingly, the magnetic flux density is proportional to the current strength. Therefore, if a magnetic flux density is sensed, a current strength should be derived accordingly.

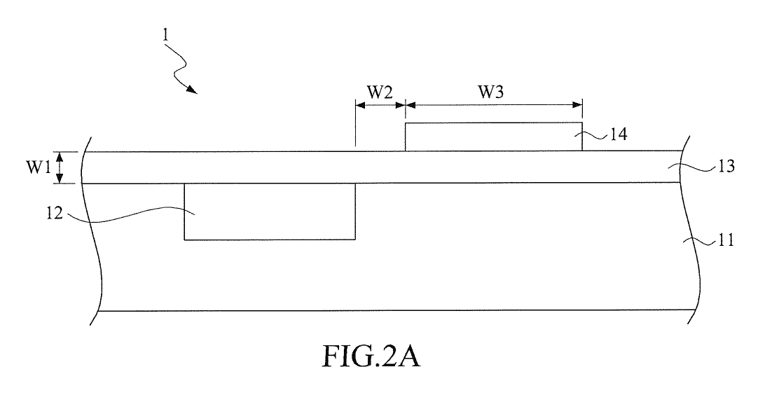

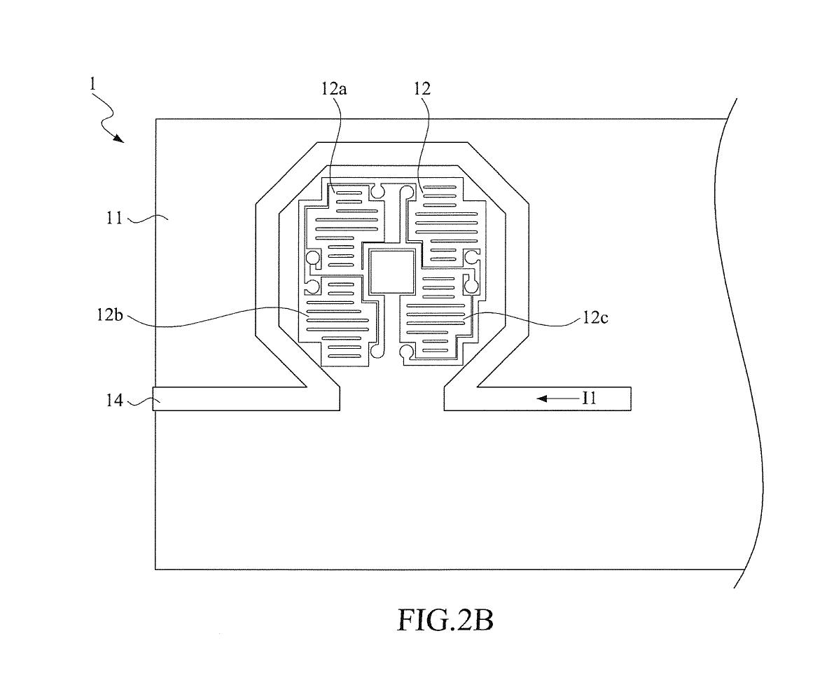

In the figures of the following embodiments of the present invention, structures irrelevant to main features of the present invention are omitted and the ratio and size of structures are adjusted for a clearer explanation and to highlight main features of the present invention; therefore, the figures are not utilized for limiting the present invention. Refer to FIG. 2A and 2B. FIG. 2A is a schematic view of a semiconductor structure for electromagnetic induction sensing according to a first embodiment of the present invention; FIG. 2B is a schematic and top view of the semiconductor structure for electromagnetic induction sensing according to the first embodiment of the present invention.

According to the first embodiment of the present invention, a semiconductor structure 1 for electromagnetic induction sensing is provided and includes a substrate 11, four Hall sensors 12, 12a, 12b and 12c, a passivation layer 13 and a current-carrying layer 14. The substrate 11 includes a Si substrate and a sapphire substrate according to the first embodiment of the present invention. The Hall sensors 12, 12a, 12b and 12c sense a magnetic field (not shown) generated by a current to be sensed I1.

The passivation layer 13 is disposed on the Hall sensors 12, 12a, 12b and 12c to cover the Hall sensors 12, 12a, 12b and 12c. The passivation layer 13 is selected from the group of an oxide, a nitride and a polyimide. The current-carrying layer 14 carries the current to be sensed I1, is disposed on the passivation layer 13 and is separated from the Hall sensors 12, 12a, 12b and 12c within an effective distance W2 so that the Hall sensors 12, 12a, 12b and 12c sense the magnetic field generated by the current to be sensed I1.

The passivation layer 13 includes an effective thickness W1 less than 100 um and the effective distance W2 is less than 500 um so that the Hall sensors 12, 12a, 12b and 12c effectively sense the current to be sensed I1. Besides, the current-carrying layer 14 includes an effective width W3 larger than 1 um and is selected from the group of a high-conductivity metal such as a copper and a silver and an alloy so that the current-carrying layer 14 carries the current to be sensed I1 effectively and sufficiently.

The current-carrying layer 14 is disposed in a route of a polygon around the Hall sensors 12, 12a, 12b and 12c. According to the first embodiment of the invention, the current-carrying layer 14 is arranged in a route similar to an octagon—this is because it is easier to form a polygon having 45 degrees, 90 degrees, or 135 degrees of each angle during a semiconductor fabrication and this is not to limit the angles of polygons for embodiments of the present invention. As a result, the current-carrying layer 14 surrounds the Hall sensors 12, 12a, 12b and 12c; when the current to be sensed I1 is carried through the current-carrying layer 14, the magnetic field generated also goes through a magnetic field sensing plane of the Hall sensors 12, 12a, 12b and 12c.

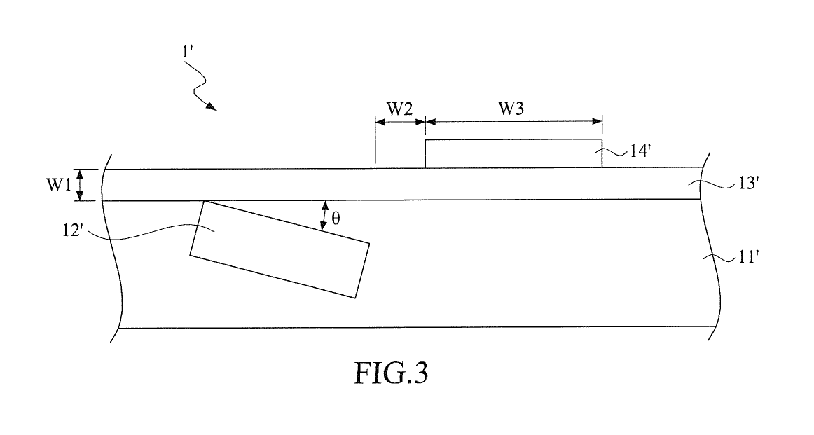

Refer to FIG. 3, a schematic view of a semiconductor structure for electromagnetic induction sensing according to a second embodiment of the present invention. A Hall sensor 12′ is formed inside a chip (not shown) and there is an angle θ between the magnetic field sensing plane of the Hall sensor 12′ and the surface of the chip. The second embodiment of the present invention is different from the first embodiment in that the Hall sensor 12′ and a passivation layer 13′ have the angle θ in-between and the angle θ is larger than 0 degree and smaller than or equal to 90 degrees.

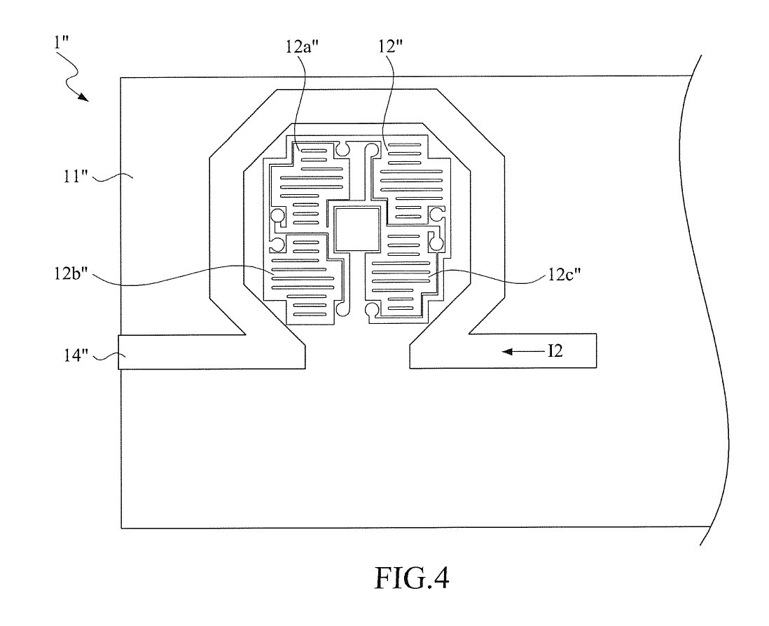

Refer to FIG. 4, a schematic and top view of a semiconductor structure for electromagnetic induction sensing according to a third embodiment of the present invention. The third embodiment of the present invention is different from the first embodiment in that a current-carrying layer 14″ having a greater effective width (not shown) so the current-carrying layer 14″ carries a current to be sensed I2 having greater strength.

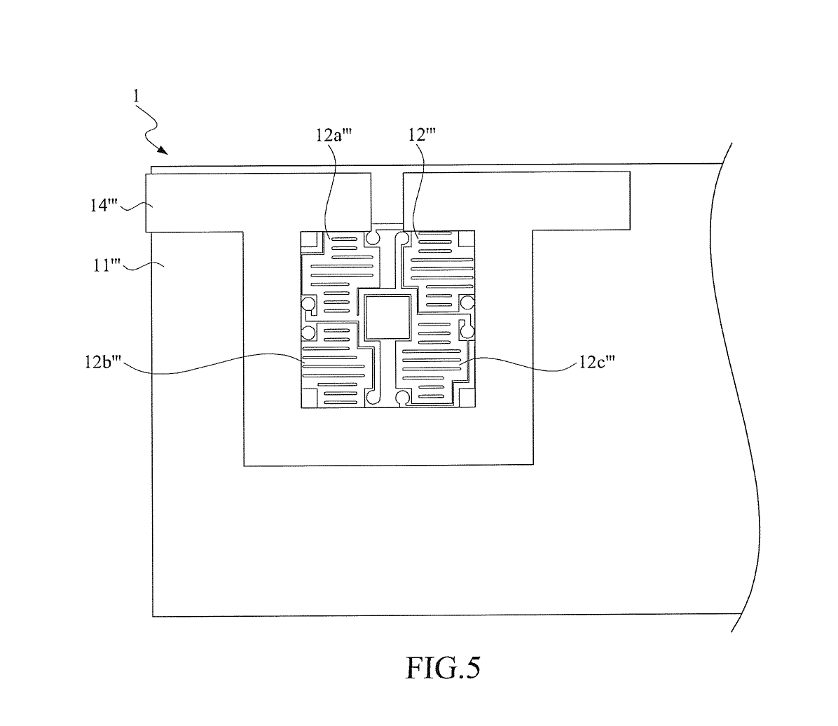

Refer to FIG. 5, a schematic and top view of a semiconductor structure for electromagnetic induction sensing according to a fourth embodiment of the present invention. The fourth embodiment of the present invention is different from the first embodiment in that a current-carrying layer 14″' surrounds Hall sensors 12″′, 12a″′, 12b″′ and 12c″′ in a route of a rectangle. It should be noted that the width of an opening of the current-carrying layer 14″′ is disposed according to various currents and is not limited as the fourth embodiment of the present invention.

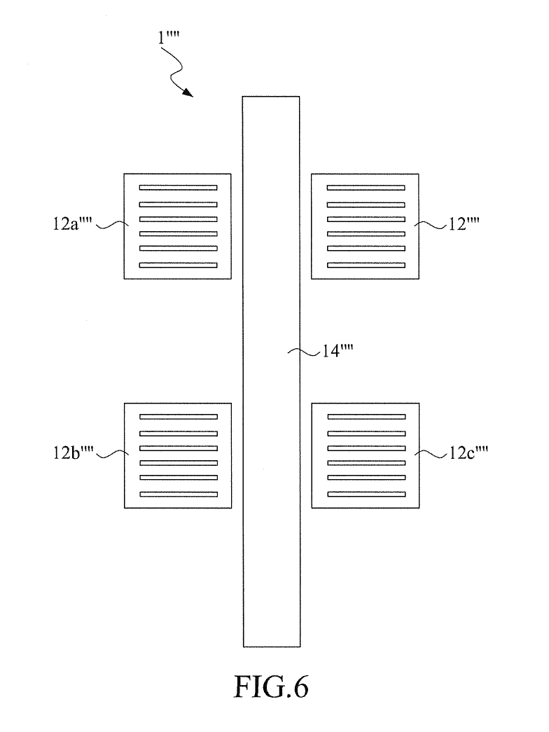

Refer to FIG. 6, a schematic and top view of a semiconductor structure for electromagnetic induction sensing according to a fifth embodiment of the present invention. A current-carrying layer 14″″ as an axis, Hall sensors 12″″, 12a″″, 12b″″ and 12c″″ are arranged in axial symmetry around the current-carrying layer 14″″ and have an effective distance (not shown) from the current-carrying layer 14″″.

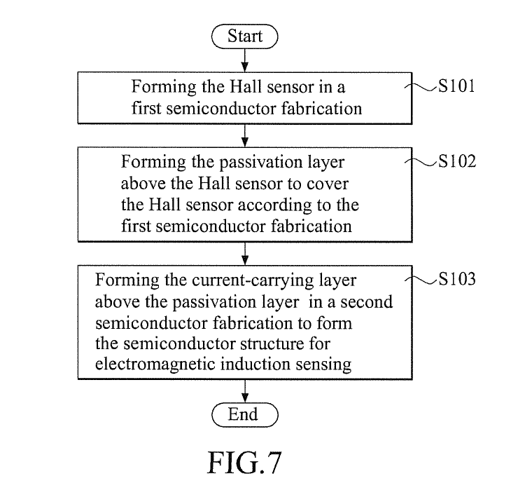

Semiconductor structures 1, 1′, 1″, 1″′ and 1″″ in the above embodiments of the present invention are fabricated during a wafer (not shown) fabrication stage, not after a wafer dicing stage. Refer to FIG. 1 and FIG. 7 together. FIG. 7 is a flow chart showing a method of manufacturing a semiconductor structure for electromagnetic induction sensing according to embodiments of the present invention. The method includes the following steps:

S101: forming the Hall sensor in a first semiconductor fabrication;

S102: forming the passivation layer above the Hall sensor to cover the Hall sensor according to the first semiconductor fabrication; and

S103: forming the current-carrying layer above the passivation layer in a second semiconductor fabrication to form the semiconductor structure for electromagnetic induction sensing.

In step S101, the first semiconductor fabrication includes diffusing, depositing and ion implanting on the substrate 11 for forming the Hall sensor 12 according to the first embodiment of the present invention.

In step S102, the first semiconductor fabrication includes diffusing, depositing and ion implanting on the Hall sensor 12 for forming the passivation layer 13 according to the first embodiment of the present invention.

In step S103, the second semiconductor fabrication includes sputter coating, depositing and etching for forming the current-carrying layer 14 and thus the semiconductor structure 1 for electromagnetic induction sensing is formed according to the first embodiment of the present invention. Due to the fact that a process of a semiconductor fabrication is highly accurate and that the semiconductor structure 1 for electromagnetic induction sensing formed is hardly deformed under effects of strains, the Hall sensor 12 senses the current to be sensed I1 carried by the current-carrying layer 14 more accurately. As a result, an interval distance between the Hall sensor and the current-carrying layer and the dielectric parameters of materials of the two are controlled more effectively.

Further, according to the first embodiment of the present invention, since the second semiconductor fabrication includes fabricating a Redistribution Layer (RDL), the current-carrying layer 14 is formed by techniques of a Redistribution Layer (RDL). According to other embodiments of the present invention, a distribution of metal with techniques of an RDL is included.

Further, a polyimide layer is formed on a chip including the Hall sensor 12 and then a metal layer is formed on the polyimide layer. Since the current-carrying layer 14 does not necessarily connect a pad of the chip electrically, the current-carrying layer 14 does not necessarily include a UBM (Under Bump Metallization) of the RDL.

In conclusion, due to the fact that a process of a semiconductor fabrication is highly accurate and that the semiconductor structure for electromagnetic induction sensing formed is hardly deformed under effects of strains, the Hall sensor senses the current to be sensed more accurately. Besides, the current-carrying layer is fabricated during a wafer fabrication and the current-carrying layer is closed to the Hall sensor; that is, the current-carrying layer is not fabricated after a wafer dicing stage. As a result, the current-carrying layer is not deformed and unstable for being squeezed by molding compound. Also, there is no need to save rooms for thermal expansion, welding and fault tolerance; spaces of a wafer are utilized more effectively.

While the present invention has been particularly shown and described with reference to a preferred embodiment, it will be understood by those skilled in the art that various changes in form and detail may be without departing from the spirit and scope of the present invention.

What is claimed is:

1. A semiconductor structure for electromagnetic induction sensing comprising:
at least a Hall sensor sensing a magnetic field generated by a current to be sensed;
a passivation layer disposed on the Hall sensor, the passivation layer covering the Hall sensor; and
a current-carrying layer disposed on the passivation layer, the current-carrying layer carrying the current to be sensed and being separated from the Hall sensor within an effective distance.

2. The semiconductor structure according to claim 1, wherein the passivation layer includes an effective thickness and the current-carrying layer includes an effective width; the effective thickness is less than 100 um, the effective distance is less than 500 um, and the effective width is larger than 1 um.

3. The semiconductor structure according to claim 1, wherein there is an angle between the Hall sensor and the passivation layer and the angle is larger than 0 degree and smaller than or equal to 90 degrees.

4. The semiconductor structure according to claim 1, wherein the passivation layer is selected from the group of an oxide, a nitride and a polyimide.

5. The semiconductor structure according to claim 1, wherein the current-carrying layer is selected from the group of a high conductivity metal and an alloy.

6. A method of manufacturing the semiconductor structure of claim 1 during a wafer fabrication, the method comprising following steps:
(a) forming the Hall sensor in a first semiconductor fabrication;
(b) forming the passivation layer above the Hall sensor to cover the Hall sensor according to the first semiconductor fabrication; and
(c) forming the current-carrying layer above the passivation layer in a second semiconductor fabrication to form the semiconductor structure for electromagnetic induction sensing, wherein the current-carrying layer is separated from the Hall sensor within the effective distance.

7. The method according to claim 6, wherein the first semiconductor fabrication includes diffusing, depositing and ion implanting, and the second semiconductor fabrication includes sputter coating, depositing and etching.

8. The method according to claim 6, wherein the second semiconductor fabrication includes fabricating a Redistribution Layer (RDL).

9. The method according to claim 6, wherein the passivation layer includes an effective thickness and the current-carrying layer includes an effective width; the effective thickness is less than 100 um, the effective distance is less than 500 um, and the effective width is larger than 1 um.

10. The method according to claim 6, wherein there is an angle between the Hall sensor and the passivation layer and the angle is larger than 0 degree and smaller than or equal to 90 degrees.

11. The method according to claim 6, wherein the passivation layer is selected from the group of an oxide, a nitride and a polyimide.

12. The method according to claim 6, wherein the current-carrying layer is selected from the group of a high conductivity metal and an alloy.
